(19) United States
(12) Patent Application Publication
(10) Pub. No.: US 2022/0102524 A1
(43) Pub. Date: Mar. 31, 2022

(54) CHIP AND METHOD FOR SELF-ALIGNED ETCHING OF CONTACTS OF CHIPS

(71) Applicant: HUA HONG SEMICONDUCTOR (WUXI) LIMITED, Wuxi (CN)

(72) Inventors: Shaojun SUN, Wuxi (CN); Dong ZHANG, Wuxi (CN); Peng HUANG, Wuxi (CN)

(73) Assignee: HUA HONG SEMICONDUCTOR (WUXI) LIMITED, Wuxi (CN)

(21) Appl. No.: 17/460,911

(22) Filed: Aug. 30, 2021

(30) Foreign Application Priority Data
Sep. 29, 2020 (CN) 202011052273.2

(51) Int. Cl. H01L 29/66; H01L 21/311

(52) U.S. Cl. CPC H01L 29/665; H01L 21/31111

(57) ABSTRACT

The present application relates to the technical field of semiconductor integrated circuit manufacturing, and in particular to a chip and a method for self-aligned etching of contacts of the chip. The chip includes a substrate layer, a salicide block layer and a dielectric layer; the salicide block layer covers the device layer; the salicide block layer comprises a first block layer and a second block layer sequentially stacked from the device layer; an etching selection ratio of the second block layer to the first block layer is high; The method includes: defining a contact pattern; performing first etching to remove the dielectric layer and the second block layer located at the position of the contact pattern, making a stop surface of the first etching be located in the first block layer; performing second etching to remove the first block layer located at the position of the contact pattern.

### CROSS-REFERENCES TO RELATED APPLICATIONS

This application claims priority to Chinese patent application No. CN 202011052273.2, filed at CNIPA on Sep. 29, 2020, and entitled “CHIP AND METHOD FOR SELF-ALIGNED ETCHING OF CONTACTS OF CHIP”, the disclosure of which is incorporated herein by reference in entirety.

### TECHNICAL FIELD

The present application relates to the technical field of semiconductor integrated circuit manufacturing, and in particular to a chip capable of being subjected to self-aligned etching of contacts and a method for self-aligned etching of contacts of the chip.

### BACKGROUND

In the Back End Of Line (BEOL) process of semiconductor devices, it is necessary to fabricate a metal interconnection layer on a pre-formed semiconductor device layer, an insulating effect is achieved by a dielectric layer between the metal interconnection layer and the semiconductor device layer, and the dielectric layer is provided with contacts that can make active regions of the device layer electrically conductive to the metal interconnection layer. In order to reduce the impedance between the device layer and the metal interconnection layer and to prevent salicide from being formed, a salicide block layer is formed between the dielectric layer and the semiconductor device layer.

With the continuous development of semiconductor industry, the density of devices on a wafer is increasing, so the number of devices that can be placed on the surface of the wafer is increasing. However, the available connection space is decreasing.

For example, for a CMOS image sensor (CIS) formed by adopting an advanced process, its performance can be guaranteed by decreasing the area of source regions or drain regions. However, the space where the source regions or drain regions are located is limited by the sidewall process of the gate structure of the device, which has a higher requirement on the etching process of the contacts in the source regions or drain regions, that is, the etched contacts need to be precisely aligned with the source regions or drain regions. Once there is a deviation in alignment precision of the contacts, the sidewalls are etched through, resulting unqualified product performance.

In the related art, by improving the alignment precision, the problem that the sidewalls are etched through due to the deviation in the alignment precision can be solved. However, the improvement of the alignment precision has higher requirements on equipment and operation processes, thereby increasing the fabrication cost of the device.

### BRIEF SUMMARY

The present application provides a chip and a method for self-aligned etching of contacts of the chip, which can solve the problems that it is very difficult to improve the alignment precision of contacts and the cost is high in the prior art.

In the first aspect of the present application, the present application provides a chip capable of being subjected to self-aligned etching of contacts. The chip capable of being subjected to self-aligned etching of contacts includes a substrate layer, a salicide block layer and a dielectric layer;

a device layer is formed on the substrate layer; the device layer includes a plurality of devices, and each device includes a gate structure and source and drain regions on the two sides of the gate structure; a sidewall structure is formed on the side of the gate structure close to the source and drain regions;

the salicide block layer covers the device layer; the salicide block layer includes a first block layer and a second block layer sequentially stacked from the device layer; an etching selection ratio of the second block layer to the first block layer is high; an etching selection ratio of the sidewall structure to the first block layer is high;

the dielectric layer is formed on the salicide block layer.

According to some embodiments, the material component of the first block layer includes silicon-enriched silicon dioxide.

According to some embodiments, the material component of the second block layer includes silicon nitride.

According to some embodiments, the dielectric layer includes a contact etch stop layer and an insulating layer sequentially stacked from the salicide block layer.

According to some embodiments, the etching selection ratio of the second block layer to the first block layer is greater than 8:1.

In the second aspect of the present application, the present application provides a method for self-aligned etching of contacts of a chip. The method for self-aligned etching of contacts at least includes the following steps:

providing the chip capable of being subjected to self-aligned etching of contacts according to the first aspect of the present application;

defining a contact pattern on the chip through a photolithography process;

performing first etching according to the contact pattern to remove the dielectric layer and the second block layer located at the position of the contact pattern, wherein an etching selection ratio of the second block layer to the first block layer is high, making a stop surface of the first etching be located in the first block layer;

performing second etching according to the contact pattern to remove the first block layer located at the position of the contact pattern and covering the source and drain regions, and to reserve the first block layer located at the position of the contact pattern and covering the sidewall structure.

According to some embodiments, the second etching is anisotropic etching.

According to some embodiments, during the second etching, the etching rate of the first block layer located at the position of the contact pattern and covering the source and drain regions is greater than the etching rate of the first block layer covering the sidewall structure.

The technical solution of the present application at least has the following advantages: by making the etching selection ratio of the second block layer to the first block layer be high, the first block layer covering the sidewall structure is reserved, the first block layer covering the sidewall structure can prevent the sidewall structure from being etched through due to the deviation in the alignment precision of the contacts, a self-aligned etching effect can be achieved, the requirement on the alignment precision of the contacts is lower, and the process difficulty and cost can be reduced.

### BRIEF DESCRIPTION OF THE DRAWINGS

In order to more clearly describe the specific embodiments of the present application or the technical solution in the prior art, the drawings which need be used in the description of the specific embodiments or the prior art will be briefly introduced below. Apparently, the drawings described below are some embodiments of the present application. Those skilled in the art may obtain other drawings according to these drawings without contributing any inventive labor.

FIG. 1a illustrates a sectional structural schematic view of a chip capable of being subjected to self-aligned etching of contacts provided by one embodiment in the first aspect of the present application.

FIG. 1b illustrates a sectional structural schematic view of a chip capable of being subjected to self-aligned etching of contacts provided by another embodiment in the first aspect of the present application.

FIG. 2 illustrates a flowchart of a method for self-aligned etching of contacts of a chip provided by one embodiment in the second aspect of the present application.

FIG. 3a illustrates a sectional structural schematic view of a chip after step S2 is completed in one embodiment in the second aspect of the present application.

FIG. 3b illustrates a sectional structural schematic view of a chip after step S3 is completed in one embodiment in the second aspect of the present application.

FIG. 3c illustrates a sectional structural schematic view of a chip after step S4 is completed in one embodiment in the second aspect of the present application.

### DETAILED DESCRIPTION

The technical solution of the present application will be described below clearly and completely with reference to the drawings. Apparently, the described embodiments are partial embodiments of the present application, instead of all embodiments. Based on the embodiments of the present application, all other embodiments obtained by those skilled in the art without contributing any inventive labor shall fall into the scope of protection of the present application.

In the description of the present application, it should be noted that the orientation or position relationships indicated by the terms such as “center”, “top”, “bottom”, “left”, “right”, “vertical”, “horizontal”, “inside” and “outside” are based on the orientation or position relationships illustrated in the drawings, for the purpose of conveniently describing the present application and simplifying the description, rather than indicating or implying that the device or component referred to must have a specific orientation and be constructed and operated in a specific orientation, and shall not be understood as limitations to the present application. In addition, the terms “first”, “second” and “third” are used only for the purpose of description, and shall not be understood as indicating or implying relative importance.

In the description of the present application, it should be noted that, unless otherwise specified and limited, the terms “mounting”, “interconnection” and “connection” shall be understood in a broad sense. For example, it may be fixed connection, detachable connection, or integrated connection; it may be mechanical connection or electrical connection; it may be direct connection or indirect connection through an intermediate dielectric; it may also be internal connection of two components, wireless connection or wired connection. Those skilled in the art may understand the specific meaning of the above terms in the present application according to the specific circumstances.

In addition, the technical features described below in different embodiments of the present application can be combined with each other as long as they do not constitute a conflict.

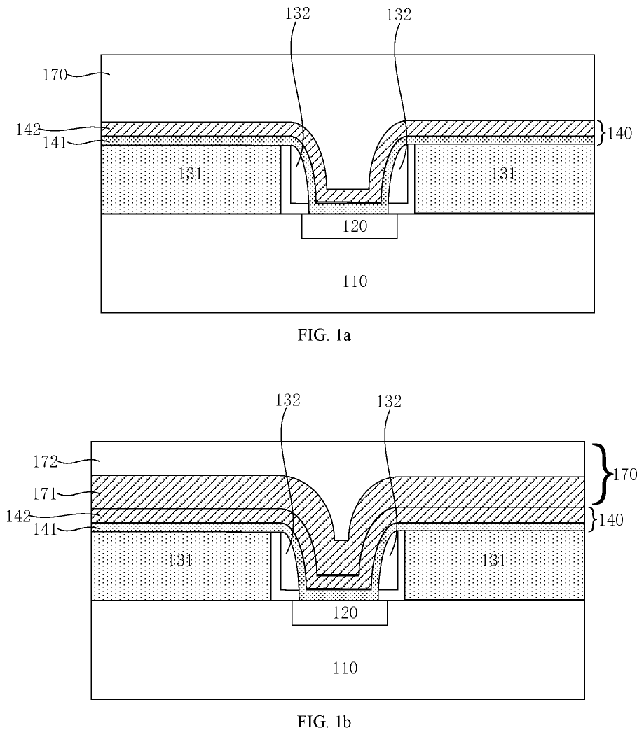

In the first aspect of the present application, one embodiment provides a chip capable of being subjected to self-aligned etching of contacts. FIG. 1a illustrates one embodiment of the chip capable of being subjected to self-aligned etching of contacts. The chip includes a substrate layer 110, a salicide block layer 140 and a dielectric layer 170.

A device layer is formed on the substrate layer 110; the device layer includes a plurality of devices, and each device includes a gate structure 131 and source and drain regions 120 on the two sides of the gate structure 131; a sidewall structure 132 is formed on the side of the gate structure 131 close to the source and drain regions 120.

The salicide block layer 140 covers the device layer; the salicide block layer 140 includes a first block layer 141 and a second block layer 142 sequentially stacked from the device layer; an etching selection ratio of the second block layer 142 to the first block layer 141 is high.

The dielectric layer 170 is formed on the salicide block layer 140.

FIG. 1b illustrates another embodiment of the chip capable of being subjected to self-aligned etching of contacts. In this embodiment, based on the structure illustrated in FIG. 1a, the dielectric layer 170 includes a contact etch stop layer 171 and an insulating layer 172 sequentially stacked from the salicide block layer 140.

For the embodiments illustrated in FIG. 1a and FIG. 1b, the material component of the first block layer 141 includes silicon-enriched silicon dioxide, the material component of the second block layer 142 includes silicon nitride, and the etching selection ratio of the second block layer 142 to the first block layer 141 is greater than 8:1.

In the embodiment of the chip capable of being subjected to self-aligned etching of contacts provided by the present application, by making the etching selection ratio of the second block layer to the first block layer be high, the problem that the sidewall structure is etched through due to the deviation in the alignment precision of the contacts can be avoided, the etching of the contacts can be finally stopped on the sidewall structure, and a self-aligned etching effect can be achieved. In the embodiment of the chip capable of being subjected to self-aligned etching of contacts provided by the present application, the requirement on the alignment precision of the contacts is lower, and the process difficulty and cost can be reduced.

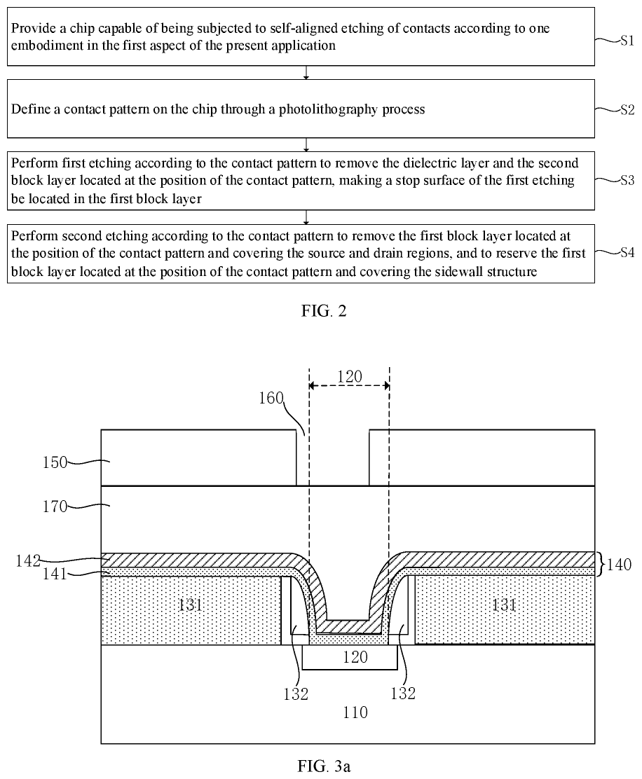

In the second aspect of the present application, one embodiment provides a method for self-aligned etching of contacts of a chip. FIG. 2 illustrates a flowchart of the method for self-aligned etching of contacts of the chip. Referring to FIG. 2, the method for self-aligned etching of contacts of the chip includes the following steps:

In step S1, the chip capable of being subjected to self-aligned etching of contacts according to any embodiment in the first aspect of the present application is provided.

FIG. 1 illustrates a sectional structural schematic view of the chip capable of being subjected to self-aligned etching of contacts according to one embodiment in the first aspect of the present application is provided.

In step S2, a contact pattern is defined on the chip through a photolithography process.

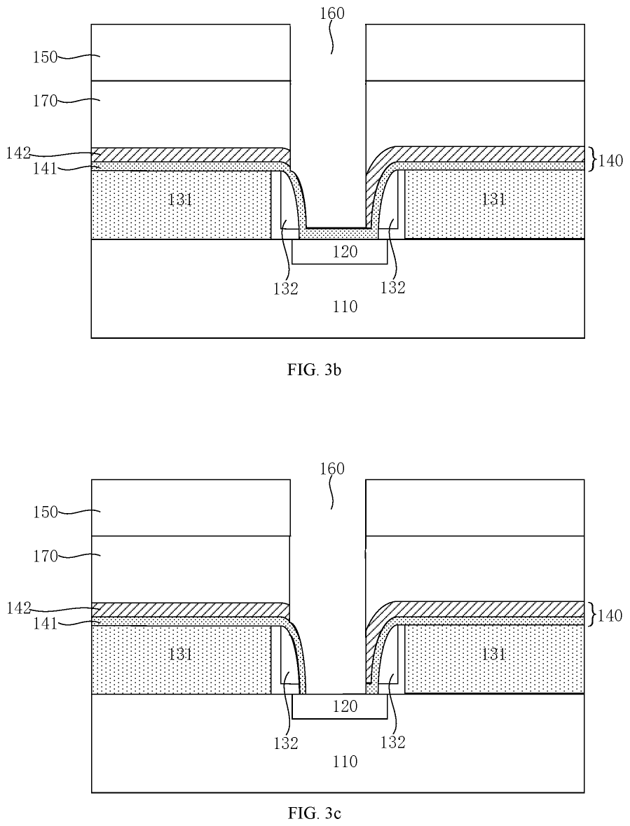

The present embodiment will be described by taking that there is a certain deviation in the alignment precision of the contacts under the situation of substantial alignment with the source and drain regions of the chip device as an example. FIG. 3a illustrates a sectional structure of the chip on which a contact pattern is defined. A photoresist 150 is coated on the upper surface of the chip, and a contact pattern 160 is defined on the photoresist 150 through a photolithography process, the contact pattern 160 is substantially aligned with the source and drain regions 120, and FIG. 3a illustrates a position which is leftwards deviated from the source and drain regions 120.

In step S3, first etching is performed according to the contact pattern to remove the dielectric layer and the second block layer located at the position of the contact pattern. An etching selection ratio of the second block layer to the first block layer is high, making a stop surface of the first etching be located in the first block layer.

FIG. 3b illustrates a sectional structural schematic view of the chip after step S3 is completed. Referring to FIG. 3b, first etching is performed according to the contact pattern 160 to remove the dielectric layer 170 and the second block layer 142 at the position of the contact pattern 160. Under the situation that the contact pattern 160 is substantially aligned with the source and drain regions 120, the alignment precision is leftwards deviated for a certain distance. Since the alignment precision is leftwards deviated, after the first etching is performed according to the contact pattern 160, the dielectric layer 170 and the second block layer 142 on the sidewall structure 130 on the left side of the source and drain regions 120 are partially removed.

For the related art, if a deviation in the alignment precision occurs, when etching is performed according to the contact pattern, not only the dielectric layer and the salicide block layer on the sidewall structure are etched, but also the sidewall structure at the position of the contact pattern is removed until it is etched to the surface of the substrate layer, resulting in device leakage and affecting device performance.

However, in the present embodiment, even if a deviation in the alignment precision occurs, when the first etching is performed, since the etching selection ratio of the second block layer 142 to the first block layer 141 is high, the etching can only remove the dielectric layer 170 and the second block layer 142 at the position of the contact pattern 160, and the stop surface of the first etching is located in the first block layer 141. Since the sidewall structure 132 is covered with the first block layer 141, the sidewall structure 132 is not etched through, thus achieving a self-aligned etching effect.

In one embodiment in which the stop surface of the first etching is located in the first block layer 141, the stop surface of the first etching may be located on the upper surface of the first block layer 141, that is, the first block layer 141 is not completely removed by the first etching. In another embodiment in which the stop surface of the first etching is located in the first block layer 141, the stop surface of the first etching may be located between the upper surface and the lower surface of the first block layer 141, that is, the first block layer 141 is only partially removed by the first etching process.

In step S4, second etching is performed according to the contact pattern to remove the first block layer located at the position of the contact pattern and covering the source and drain regions, and to reserve the first block layer located at the position of the contact pattern and covering the sidewall structure.

FIG. 3c illustrates a sectional structural schematic view of the chip after step S4 is completed. Referring to FIG. 3c, etching is further performed on the basis of the device structure after step S3 is completed. The surface of the first block layer 141 at the position of the contact pattern 160 is exposed after step S3 is completed. The second etching is anisotropic etching. The etching rate of the first block layer 141 located at the position of the contact pattern 160 and covering the source and drain regions 120 is greater than the etching rate of the first block layer 141 covering the sidewall structure. Thus, after the second etching is completed, the first block layer 141 located at the position of the contact pattern 160 and covering the source and drain regions 120 can be removed, and the first block layer 141 located at the position of the contact pattern 160 and covering the sidewall structure 132 can be reserved. The first block layer 141 covering the sidewall structure 132 can prevent the sidewall structure 132 from being etched through.

In one embodiment in which the stop surface of the second etching is located on the sidewall structure 132, the stop surface of the second etching may be located on the upper surface of the sidewall structure 132, such that the upper surface of the sidewall structure 132 is exposed after the second etching is completed, that is, the sidewall structure 132 is not completely removed by the second etching.

In the method for self-aligned etching of contacts of the chip provided by the embodiment of the present embodiment, by making the etching selection ratio of the second barrier layer to the first barrier layer be high, the first block layer covering the sidewall structure is reserved, the first block layer covering the sidewall structure can prevent the sidewall structure from being etched through due to the deviation in the alignment precision of the contacts, a self-aligned etching effect can be achieved, the requirement on the alignment precision of the contacts is lower, and the process difficulty and cost can be reduced.

Apparently, the above embodiments are only examples for clear description, instead of limitations to the embodiments. On the basis of the above description, those skilled in the art may make other different types of changes or variations. It is not necessary and impossible to enumerate all the embodiments here. The apparent changes or variations thus derived are still within the scope of protection of the present application.

What is claimed is:

1. A chip capable of being subjected to self-aligned etching of contacts, wherein the chip capable of being subjected to self-aligned etching of contacts comprises a substrate layer, a salicide block layer and a dielectric layer;
a device layer is formed on the substrate layer; the device layer comprises a plurality of devices, and each device comprises a gate structure and source and drain regions on the two sides of the gate structure; a sidewall structure is formed on the side of the gate structure close to the source and drain regions;
the salicide block layer covers the device layer; the salicide block layer comprises a first block layer and a second block layer sequentially stacked from the device layer; an etching selection ratio of the second block layer to the first block layer is high; an etching selection ratio of the sidewall structure to the first block layer is high;
the dielectric layer is formed on the salicide block layer.

2. The chip capable of being subjected to self-aligned etching of contacts according to claim 1, wherein the material component of the first block layer comprises silicon-enriched silicon dioxide.

3. The chip capable of being subjected to self-aligned etching of contacts according to claim 1, wherein the material component of the second block layer comprises silicon nitride.

4. The chip capable of being subjected to self-aligned etching of contacts according to claim 1, wherein the dielectric layer comprises a contact etch stop layer and an insulating layer sequentially stacked from the salicide block layer.

5. The chip capable of being subjected to self-aligned etching of contacts according to claim 1, wherein the etching selection ratio of the second block layer to the first block layer is greater than 8:1.

6. A method for self-aligned etching of contacts of a chip, wherein the method for self-aligned etching of contacts at least comprises the following steps:
providing the chip capable of being subjected to self-aligned etching of contacts according to claim 1;
defining a contact pattern on the chip through a photolithography process;
performing first etching according to the contact pattern to remove the dielectric layer and the second block layer located at the position of the contact pattern, wherein an etching selection ratio of the second block layer to the first block layer is high, making a stop surface of the first etching be located in the first block layer;
performing second etching according to the contact pattern to remove the first block layer located at the position of the contact pattern and covering the source and drain regions, and to reserve the first block layer located at the position of the contact pattern and covering the sidewall structure.

7. A method for self-aligned etching of contacts of a chip according to claim 6, wherein the second etching is anisotropic etching.

8. A method for self-aligned etching of contacts of a chip according to claim 7, wherein during the second etching, the etching rate of the first block layer located at the position of the contact pattern and covering the source and drain regions is greater than the etching rate of the first block layer covering the sidewall structure.
